(19) United States
(12) Patent Application Publication
(10) Pub. No.: US 2012/0125666 A1
(43) Pub. Date: May 24, 2012

(54) MULTI-LAYERED PRINTED CIRCUIT BOARD WITH CONDUCTIVE TEST AREAS AS WELL AS METHOD FOR DETERMINING A MISALIGNMENT OF AN INNER LAYER

(75) Inventors: Arno KLAMMINGER, Graz (AT); Heinz Habenbacher, St. Peter (AT); Wilhelm Lobner, Leoben (AT)

(73) Assignee: AT & S AUSTRIA TECHNOLOGIE & SYSTEMTECHNIK AKTIENGESELLSCHAFT FABRIKSGASSE 13

(21) Appl. No.: 13/291,674

(22) Filed: Nov. 8, 2011

Related U.S. Application Data
(62) Division of application No. 11/883,949, filed on Mar. 31, 2008, now abandoned.

(30) Foreign Application Priority Data
Mar. 1, 2005 (AT) 344/2005

(51) Int. Cl. H05K 1/00

(52) U.S. Cl. 174/250

(57) ABSTRACT

A multi-layered printed circuit board (1) including conductive test areas (7) on at least one inner layer (2) for determining a possible misalignment of an inner layer, or a misalignment of an inner layer structuring, respectively, wherein the conductive test areas include ring structures (7.i) arranged in rows and defining inner, non-conductive areas (8.i) of various sizes, and having through-contacting bore holes (5) in the region of the rest areas (7).

The invention relates to a multi-layered printed circuit board comprising conductive test areas on at least one inner layer for determining a possible misalignment of an inner layer, or a misalignment of an inner layer structuring, respectively, wherein the conductive test areas are comprised of ring structures arranged in rows and defining inner, non-conductive areas of various sizes, and having through-contacting bore holes in the region of the test areas, wherein these bore holes are provided in the region of the inner, non-conductive areas, in case there is no misalignment or a negligible misalignment, yet wherein, in case there is a non-negligible misalignment, at least one bore hole is present in the region of one of the conductive ring structures, thus having a conductive connection with the ring structure.

Furthermore, the invention relates to a method for determining a possible misalignment of an inner layer, or of an inner layer structuring, respectively, in a multi-layered printed circuit board, by means of conductive test areas and through-contacting bore holes, wherein at least one inner layer of the printed circuit board is provided with test areas in the form of ring structures arranged in rows, which ring structures each define a non-conductive inner area, wherein the inner areas of the ring structures have a number of different sizes, and wherein, in case there is no misalignment or a negligible misalignment, through-contacting bore holes provided in the region of the test areas are present in the region of the inner areas, and in case there is a misalignment, they are present at least individually in the region of a conductive ring structure and form a conductive connection with the latter, whereby, when a voltage is applied between the bore holes and the ring structures, depending on the misalignment, a short circuit is found in certain pairs of bore holes and ring structures, from which the misalignment of the inner layer, or inner layer structuring, respectively, is concluded.

It has been known that registering errors of individual layers of the printed circuit boards and/or of structurings on such layers result repeatedly during the production of multi-layered printed circuit boards, these registering errors, also termed inner layer offsets, being the more critical, the higher the density of the components to be applied on the printed circuit boards, and the narrower the conductive tracks of the structurings on the layers of the printed circuit boards. These registering errors are due to various influences prevailing during the production of the printed circuit boards, material elongations and material shrinkages during the production process being a main cause thereof. Other causes may reside in a warping of the inner layers during the pressing of multilayer stacks, yet also in so-called image transfer errors that might occur when carrying out photo-etching techniques. Above all, also film changes occurring during the production process may result in an inner layer offset or in an offset of structurings provided on inner layers.

In U.S. 6,297,458 B, a technique has been proposed in order to examine printed circuit boards for a misalignment of inner layers by using specially structured test areas in a non-distructive measurement method. In this case, ring-shaped test areas are provided on different inner layers of the multi-layered printed circuit boards, which test areas have different radial widths, so that the circle areas which are present inside the circular rings and non-conductive, have different sizes and diameters, respectively. The annular test areas are arranged on an inner layer separated from each other, whereas on another inner layer they are interconnected by conductive material strips. In the region of these ring structures, bore holes are then made which are copper-plated, i.e. through-contacted bore-holes. During the test for determining the registering error or the misalignment, test needles are introduced in parallel to each other into these bore holes by means of a needle tester, and with the help of a further needle, a contact is provided to the conductively interconnected rings. Depending on the misalignment, none, one or several needles come into contact with the ring-shaped test areas resulting in a short circuit, and depending on in how many needles such a short-circuit is found, the magnitude, i.e. the amount of the misalignment, in a direction given by the direction of rows of the ring-shaped test areas can be determined. What is disadvantageous in this known technique is that an offset of inner layers or inner layer structures in one row of test areas can only be determined in one direction; if an offset is to be determined also in another direction, a row of ring-shaped test areas must be provided also in this direction on each one of the two observed inner layers of the printed circuit board.

From the internet site www.perfectest.com on the other hand, a technique for determining registering errors at inner layers of printed circuit boards is disclosed, in which in x-direction and in y-direction elongate areas are provided in pairs the thickness of which increases or decreases stepwise. Ideally, the through-contacting bore holes produced thereafter are present in the space between these conductive areas (earth areas), without making contact with one of these earth areas; in case of an offset of one inner layer relative to the other one, however, individual ones or all the bore holes will come to lie relative to these earth areas such that they make contact with these. Here, there are test area groups arranged in two directions in order to detect an offset in these two directions, and also to be able to determine the amount thereof due to the gradings of the earth areas. The amount of the offset will result from determining which needle of the row of needles in the needle tester still detects a short circuit with earth (ground), and which needle as the next one does no longer do so. Yet, also here, a rather restricted checking of registering errors is possible at comparatively high expenditures.

It is now an object of the invention to provide a multi-layered printed circuit board, and a method of determining a misalignment at inner layers of such printed circuit boards, respectively, wherein it shall be possible on the basis of special structures of the test areas to determine a misalignment not only in terms of its amount, but also according to random directions, in a simple manner depending on the aim envisaged. In particular, the test area structures for this shall be comparatively simple and also space-saving.

To achieve this object, the invention provides a multi-layered printed circuit board as well as a method for determining a possible misalignment of an inner layer, or of an inner layer structuring, respectively, in a multi-layered printed circuit board according to the independent claims. Advantageous embodiments and further developments are the subject matter of the dependent claims.

According to the invention, the test area ring structures are segmented so that in each case there result several segments separated from each other in circumferential direction by non-conductive separating regions. It should be mentioned here that the ring structures need not necessarily be exactly circular, but, depending on the individual case of application, may also be more or less oval, or comparatively angular, in the manner of an out-of-roundness. As a rule, however, a misalignment determination of the same type in all the angular directions that are possible and desired will be sought, and for this it will be advantageous if in each case equally sized segments are provided, and if the segments in each case are circle segments, i.e. segments of circular rings as individual test areas. Depending on the number of segments, there may be a comparatively rough or a fine differentiation concerning the misalignment of the inner layers, and a particular good compromise in which also the misalignment according to the direction can be determined sufficiently, an embodiment has been found in which four segments are provided for each ring structure. To simplify the evaluation of the measurement results, it is furthermore suitable if at each ring structure, the non-conductive separating regions separating the segments from each other are of equal width, so that the distances of the segments from each other will be equally large. In particular, it is advantageous if the separating regions between the segments of all the ring structures of one row all have the same width.

For determining registering errors of inner layers, according to a simple, particularly preferred embodiment it is provided that through-contacting bore holes extend from a printed circuit board layer on which they are provided with contact areas, towards an inner layer provided with test area ring structures. Thereinstead or, preferably, also in addition thereto it is also suitable if through-contacting bore holes extend from an inner layer provided with test area ring structures towards another printed circuit board layer which comprises a common, coherent conductive area as contact area for the bore holes. In this manner, that misalignment, or that partial contribution to the total misalignment which is given simply by the misalignment of the photo process during structuring relative to the boring process can be determined separately.

With the technique according to the invention, not only a resolution as fine as desired is possible for the amount of the misalignment through the special test area structure, but also the direction of the misalignment can be determined in a simple manner, as has been mentioned, this directional determination also allowing for a practically random small angular subdivision, depending on the number of ring segments used. As has been mentioned, preferably four segments each are provided, since, as practical tests have shown, as a rule these are sufficient; it is, however, also conceivable to use six or eight ring segments, e.g., per test area ring structure in order to enable an even finer angular division. Yet, on the other hand, also merely three ring segments may very well suffice in order to be able to determine the orientation of a misalignment of an inner layer, or of a structuring, respectively, with sufficient precision.

With the help of such a measurement technique, as has been described, not only multi-layered printed circuit boards can be checked in a simple manner for inner layer (structure) registering errors, moreover, such a determination of a misalignment can also be effected accompanying the production of such printed circuit boards in order to be able to correctively interfere in the production of the printed circuit boards in accordance therewith so that rejects of printed circuit boards with excessive registering errors can be reduced thereby.

In the following, the invention will be explained in more detail by way of preferred exemplary embodiments to which, however, it shall not be restricted, and with reference to the drawings. In the drawings, in detail,

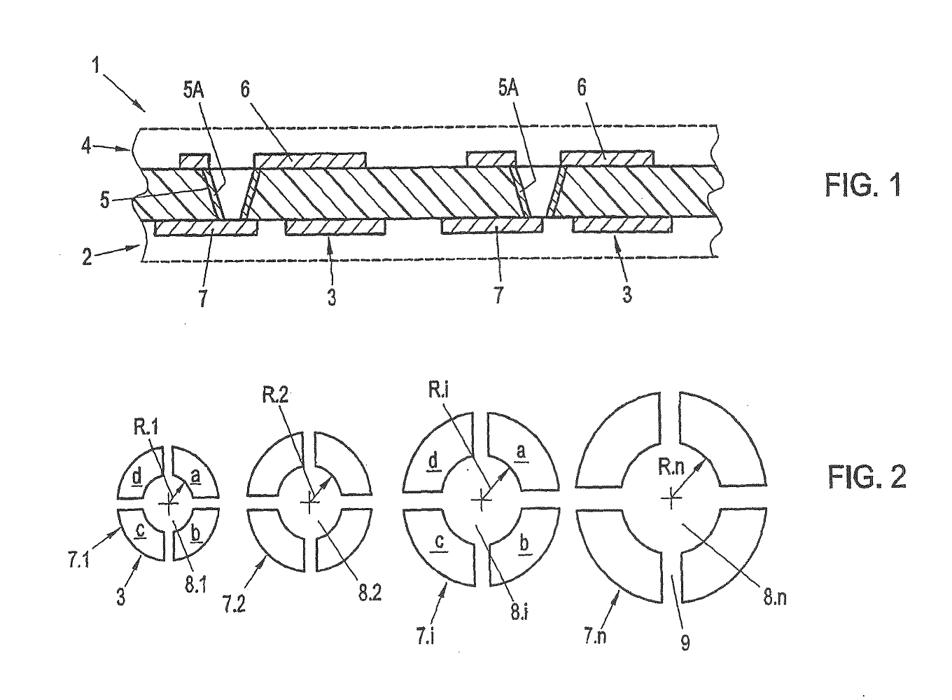

FIG. 1 shows a schematic cross-section through a part of a multi-layered printed circuit board in the region of test area ring structures, with two inner layers being illustrated one above the other;

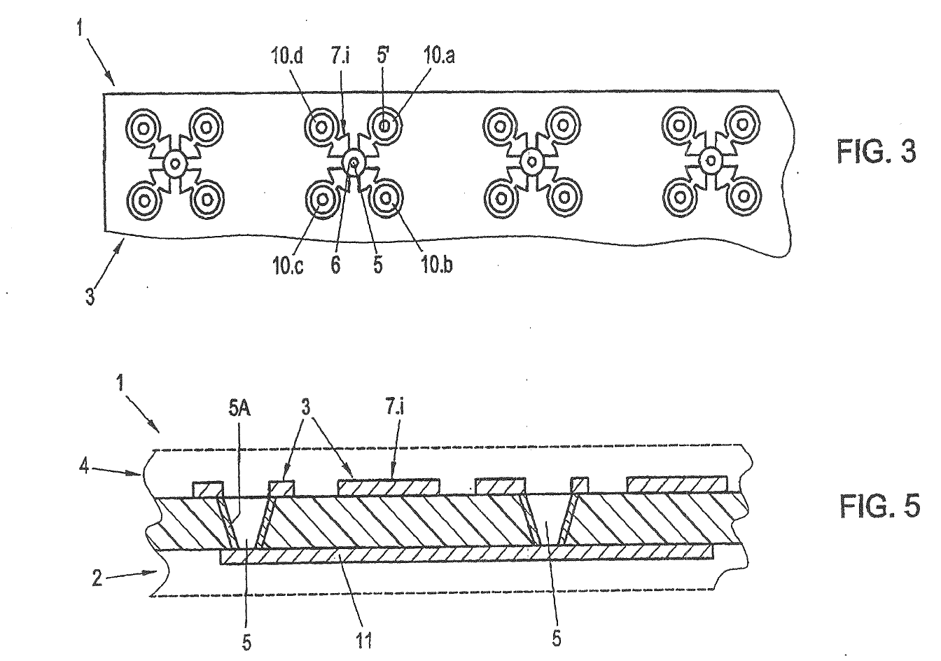

FIG. 2 shows a schematic top view onto a row of test area ring structures which each are segmented;

FIG. 3 shows the alignment of such segmented ring structures relative to through-contacting bore holes and connecting areas of the test areas segments on outer layers in a schematic top view,

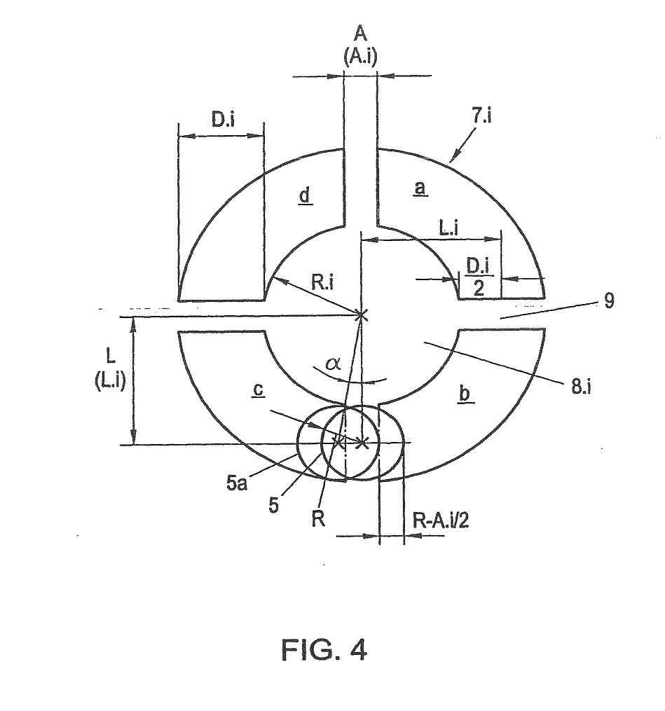

FIG. 4 shows a test area ring structure having four circle segments as well as a schematically illustrated bore hole in an illustration enlarged relative to FIG. 2, wherein the different geometric parameters important for determining the misalignment are shown; and

FIG. 5 shows a part of a multi-layered printed circuit board in a schematic cross-sectional representation similar to FIG. 1, yet here the lower inner layer is provided with a coherent, common earth area, and the upper inner layer is provided with test area ring structures having ring segments.

In FIG. 1, a sectional part of a multi-layered printed circuit board 1 is schematically illustrated in cross-section. On an inner layer 2 which, according to the illustration of FIG. 1, is the lower inner layer, a pattern 3 of conductive test areas is provided, and for this purpose, usual photo-etching techniques as are common in the course of structuring of conductive layers of printed circuit boards, or printed circuit board layers, respectively, may be used. One example of such a pattern 3 will be explained in more detail hereinafter by way of FIG. 2. From an inner layer 4, which is the upper inner layer according to FIG. 1, bores 5 extend, e.g. through a synthetic resin layer not further denoted in the drawing, towards the lower inner layer 2. These bores, called bore holes 5 hereinafter, are coated with a conductive material, in particular copper, on their inner wall, and on the upper side, on the lower side of the upper inner layer 4—e.g. also by means of a conventional photo-etching technique process,—contact areas 6 for contacting the bore holes 5 are provided. These contact areas 6 or earth areas appropriately are also termed “lands”. Copper-plating of the bore holes 5 is denoted by 5A in FIG. 1, and the bore holes 5 thus obtained commonly are denoted as “through-contacting bore holes”.

In the embodiment according to FIG. 1, the bore holes 5 are made from the upper inner layer 4 towards the lower inner layer 2, and after the boring process and after copper-plating of the bore holes 5, the pattern of the contact areas 6 is provided, i.e. structured, on the upper inner layer 4 during the aforementioned photo process.

As can be seen from FIG. 1, the bore holes 5 meet conductive test areas 7 of the pattern 3 on the lower inner layer 2 which is due to a misalignment or a registering error between the two inner layers 2, 4. Ideally, the bores would meet non-conductive areas of the pattern 3, as illustrated in detail hereinafter by way of FIGS. 2 and 4.

According to FIG. 2, the test area pattern 3 consists of a row of test area ring structures 7.1, 7.2, . . . 7.i, wherein, preferably, circular ring structures as illustrated in FIG. 2 are provided. These ring structures 7.i, with i=1, 2, . . . n (in the example shown, n=4), each, by way of example, exhibit four circular ring segments a, b, c and d. These ring structures 7.1 define, i.e. enclose, each an inner circular, non-conductive area 8.1, 8.2, . . . 8.i . . . 8.n. The radii R.i, with i=1, 2, . . . n, of these non-conductive, circular inner areas 8.i, become increasingly larger in row direction within such a row pattern 3 of test areas, as is visible from FIG. 2. For the example illustrated, with n=4, thus it can be specifically written: R.4>R.3>R.2>R.1. The radius difference ΔR=R.2−R.1 etc. can be chosen to be as fine as desired, depending on the production tolerances, and, thus, such a test area row 3 will cover a measurement range with freely selectable graduation for determining the amount of a misalignment between the inner layers concerned, e.g. the inner layers 2 and 4 according to FIG. 1.

Moreover, structuring of the ring structures 7.1 with the ring segments a, b, c and d which are electrically separated from each other by non-conductive separating regions 9 will make it possible to determine the direction of the misalignment or warp, i.e. the registering error. Depending on the number of ring segments, a, b, c, d, . . . , a more or less fine resolution will result, by means of which the directional deviation in the orientation of the inner layers relative to each other can be determined.

The specially structured test areas or earth areas 7.i of the pattern 3 appropriately are also termed “fiducial”, and as has already been stated in the beginning, basically such a non-destructive measurement method for determining registering errors between inner layers or inner layer structures by means of such fiducials has been known. With the present technique, however, quite a special structuring of these fiducials or test areas 7.i has been provided so as to be able to determine a misalignment between inner layers both in terms of its amount and also in terms of its direction. Accordingly, with the present technique, the determination of the total offset between inner layers and, furthermore, also the separate determination of individual influences on the total offset are enabled, cf. also the following description of FIG. 5.

Before discussing in detail the principle of the determination of the misalignment by way of the geometries provided and with reference to FIG. 4, the layout of a test area row 3 shall be explained by way of FIG. 3 in a schematic top view, wherein for the sake of simplicity, conductive areas have been drawn in full lines in FIG. 3, even though they are provided on various layers of the multi-layered printed circuit board 1.

In detail, in FIG. 3 the test area ring structures 7.i provided on an inner layer, e.g. on inner layer 2 according to FIG. 1, can be seen having the circular ring segments a, b, c and d according to FIG. 2 and not further denoted in FIG. 3, and within the latter, a through-contacting bore 5 is visible in the individual ring structures, which bore 5 has an associated ring-shaped contact area 6 on another inner layer (inner layer 4 in FIG. 1). For providing an electric connection, the individual ring segments a, b, c and d of the ring structure 7.i have associated contact areas 10.a, 10.b, 10.c and 10.d on an outer layer, and through-contacting bore holes 5′ are provided in a comparable manner for an electric connection with the respective circular ring segments a, b, c and d. Such an arrangement is provided for each ring structure of the row or of the row-like pattern 3, wherein the inner diameters of the ring structures, i.e. the radii r.i of the non-conductive inner areas 8.i (cf. FIG. 2) or, generally, the size of the inner non-conductuive areas 8.i, increases step-wise in row direction. It should be men- tioned here that, in principle, the ring structures 7.i may also have shapes that deviate from an exact circular ring shape, such as oval shapes or also square shapes with rounded corners etc., an exact circular ring shape, however, being preferred with a view to the uniformity of the prerequisites prevailing in all the detectable measurement directions and required for the determination of the misalignment.

Ideally, if there is no, or practically no, misalignment between the inner layers, or inner layer structures, respectively, all the through-contacting bore holes 5 will encounter the inner, non-conductive areas 8.i of the test ring structures 7.1. Now, if due to an inner layer or bore misalignment, a bore hole 5 touches a ring segment a, b, c, d, optionally also two adjacent ring segments simultaneously, a short circuit will occur between the through-contacting bore hole 5, to be more precise, the contact area G on the upper inner layer 4 according to FIG. 1 and the corresponding ring segment a, b, c or d of the respective ring structure 7.i when a voltage is applied. Due to the increasing size of the radii R.i of the inner, non-conductive areas 8.i, the amount, i.e. the magnitude of the misalignment, can be determined by evaluating at which ring structure 7.i a short circuit as described has (still) occurred. Since the ring segments a, b, c, d are electrically separated from each other, also the direction of the misalignment can be determined by determining the respective ring segment with which a short circuit exists. This will be explained in more detail hereinafter by way of FIG. 4.

In FIG. 4, a test area ring structure 7.i is schematically illustrated in top view, which has a circular ring structure and has four circular ring segments a, b, c and d. As has been mentioned, these circular ring segments a, b, c, d are separated from each other by non-conductive separating areas 9 which each have the same width, the width of these separating regions 9 being denoted by A.i in FIG. 4. The non-conductive inner circular area 8.i has a radius R.i, and in the example illustrated, the individual ring segments a, b, c and d have the same radial width D. This width D may, however, very well vary, such as if in case of a radius R.i that increases from one test area ring structure to the next one, the outer radius of the circular segments remains equal, so that then the width D, or rather D.i, will successively diminish (D.i=R.external−R.i).

Moreover, by two circular rings, two through-contacting bore holes 5, 5a are illustrated which are made from a different inner layer to that inner layer which contains the ring structure 7.i, bore hole 5 in the example illustrated simultaneously meeting the two ring segments b and c and, thus, providing a short circuit to these two ring segments b, c; bore hole 5a, however, meets the ring segment c and just touches ring segment b. The diameter of each bore hole 5, and 5a, respectively, is denoted by R. The distance between the center of the circular, non-conductive inner area 8.i and the center of the ring segments, c or d, e.g., is indicated in FIG. 4 by L, and by L.i more precisely.

As has been mentioned, ideally, when there is no misalignment between the inner layers, 2 and 4, e.g., in FIG. 1, the bore holes 5 will be located substantially precisely in the middle of the inner circular, non-conductive areas 8.i. If, however, the inner layers 2, 4 are offset relative to each other, the bore holes 5 will not hit the middle of these areas 8.i or, generally, of the ring structures 7.i, but they will be shifted to the conductive test areas, i.e. towards the ring segments a, b, c and d of the ring structures 7.i Thus, if the offset V is larger than (R.i−R), the bore hole 5 will hit at least one ring segment a, b, c, d. Due to the copper-plating of the bore holes 5, thus the short circuit between the respective bore hole 5 and the respective ring segment a, b, c, d can be noted, it being possible to draw conclusions to the amount of the offset V e.g. according to the following Table 1.

TABLE 1

| One bore 5 meets | | |
|---|---|---|
| ring segments | Amount of offset | |
| of the 1^{st} fiducial 7.1 | V > R.1 − R | R.1 > R |
| of the 2^{nd} fiducial 7.2 | V > R.2 − R | R.2 > R.1 |
| of the 3^{rd} fiducial 7.3 | V > R.3 − R | R.3 > R.2 |
| of the 4^{th} fiducial 7.4 | V > R.4 − R | R.4 > R.3 |
| of the i^{th} fiducial 7.i | V > R.i − R | R.i > R.i − 1 |

The amount of offset V thus results from that short circuit which occurs at the fiducial (at that ring structure) with the largest radius.

From the short circuit of a through-contacting bore hole 5 with a specific circular ring segment a, b, c and/or d, furthermore the angular orientation of the offset V can be determined, and in the exemplary embodiment illustrated having four circular ring segments a, b, c and d per ring structure, or fiducial 7.i, respectively, the angular orientation of the offset V can be determined approximately according to the following Table 2:

TABLE 2

| A bore hole encounters | |
|---|---|
| ring segment | Angle of offset V |
| d + a | 360° − α < V < α |
| a | α < V < 90° − α |
| a + b | 90° − α < V < 90° + α |
| b | 90° + α < V < 180° − α |
| b + c | 180° − α < V < 180° + α |
| c | 180° + α < V < 270° − α |
| c + d | 270° − α < V < 270° + α |
| d | 270° + α < V < 360° − α |

For angle α it holds:

$$tan α = \frac{• R - \frac{A . i}{2} •}{L . i} , with$$

$$L . i = R . i • \frac{D . i}{2} .$$

Real exemplary values are:
R=90 μm
A=65 μm
D=200 μm
R.1=225 μm (9 mil)
R.2=250 μm (10 mil)
R.3=275 μm (11 mil)
R.4=300 μm (12 mil)

From this, α results with approximately 10°.

The angle α according to the previous designation corresponds to a maximum respective angle and defines the resolution with which the deviation of direction of the inner layer offset can be determined. For the given values and a fiducial structure with four ring segments a, b, c, d, the resolution of the angle range is approximately 20°(=2×10°), if the bore 5 hits two ring segments, b, and c, e.g., and approximately 70°(=90°−2×10°), if the bore 5 hits one ring segment only, c, e.g. If the number of ring segments is eight, the two angular resolutions for the aforementioned example values will be approximately equal and will amount to approximately 20°. Since with changing radii R.i and widths D.i also the lengths L.i will change, strictly speaking a changing angle α.i will result, too. At constant A, the angular resolution α.i will change within the fiducial row. In order to keep the angular resolution α.i constant, the value A (→A.i) must be changed within one fiducial row. One variant to the structure described thus consists in making the value A.i smaller with increasing radius R.i. For design reasons, also the width D of the ring segments could vary within one fiducial row (D.1, D.2, . . . , D.i). Thus, the previous Table 2 would change accordingly.

The number of the circular ring segments for each ring structure 7.i can be chosen at random in dependence on the printed circuit boards produced, on the process parameters and on the bore hole diameters used. The larger the number of ring segments, the finer the angular resolution as previously indicated, and the calculation according to the previous Table 2 will have to be changed accordingly. On the other hand, the magnitude of the radii R.i as well as the number of the ring structures 7.i determine the measurement range for the range of the inner layer offset V. In principle, the number of the ring structures per row can be chosen as high as desired, yet on account of the space required therefore, as well as on account of the measurement range actually relevant in practice, it will be restricted to relatively few ring structures.

Depending on the individual case, the distance A (or A.i, respectively) between the circular ring segments a, b, c, d may be chosen of equal size for all the ring structures 7.i, or it will be adapted to the size of the respective ring structure 7.i, e.g. chosen to be increasingly larger with the size of the ring structure. Similar considerations also hold for the radial width D of the ring segments a, b, c, d. In many cases, however, it is preferable to chose all the radial widths D and distances A within a respective ring structure to be of equal size.

In FIG. 5, a section of a multi-layered printed circuit board 1 is shown in a cross-sectional illustration similar to FIG. 1, in which, again, bore holes 5 are made from an inner layer 4, which is an upper layer according to this illustration, towards a lower inner layer 2. Different from FIG. 1, however, according to FIG. 5, after the boring and copper-plating procedure, the ring structures 7.i of one fiducial row 3 on the upper inner layer 4 are structured. Preferably, in addition to the bores 5 for the fiducial row 3 on the lower inner layer 2 according to FIG. 1, for thus measuring the total offset between the layers 2 and 4, the bores 5 according to FIG. 5 are made which end on the lower inner layer 2 on a common, continuous conductive area (earth area) as contact area 11. The photo-structuring of the upper inner layer 4 for forming the upper row or the upper pattern 3 according to FIG. 5 occurs after the bore holes 5 have been bored and copper-plated. Depending on how the photo-process on the upper inner layer 4 is misaligned relative to the bores 5, again certain ring segments of the individual ring structures 7.i, similarly as explained before, will now be short-circuited, however, on the upper inner layer 4 with the earth area 11 on the lower inner layer 2. From this, in analogy to the previous description, it will be possible to determine the misalignment of the structuring of the upper inner layer 4, i.e. the offset of the photo-process, relative to the bores (bore holes 5) in terms of amount and direction. In this manner, particularly that contribution to the total offset can be determined separately which occurs due to the offset of the photo-process relative to the boring process.

In order to be able to measure the respective inner layer offset on the outer layer of the printed circuit board 1 in accordance with the previously described measurement technique, the electrical connections, as previously already explained by way of FIG. 3, for the individual inwardly arranged, conductive areas, e.g. the ring segments a, b, c, d, and for the through-contacting bore holes 5, and their contact areas 6, respectively, are guided to the outer layer of the printed circuit board 1. As is furthermore known per se, the short-circuitings possibly occurring are then detected with a needle tester in a parallel process on the surface of the printed circuit board and evaluated in a computer so as to automatically determine the amount and the direction of the respective inner layer offset V.

1-15. (canceled)

16. A multi-layered printed circuit board comprising
conductive test areas on at least one inner layer for determining a possible misalignment of an inner layer, or a misalignment of an inner layer structuring, respectively,
wherein the conductive test areas are comprised of ring structures arranged in rows defining inner, non-conductive areas of various sizes, and being subdivided in circumferential direction, thereby forming segments, the segments being separated from each other in circumferential direction by non-conductive separating regions, said test area ring structures having through-contacting bore holes in the region of the test areas, these bore holes having ends in the inner, non-conductive areas of the ring structures in a case of no misalignment or of a negligible misalignment, whereas, in case there is a non-negligible misalignment, at least one bore hole ends in the region of one of the conductive ring structures, thus having a conductive connection with the ring structures;
wherein such through-contacting bore holes extend from an inner layer provided with test area ring structures towards another printed circuit board layer which has a common, continuous, conductive area as contact area for the bore holes.

17. The printed circuit board according to claim 16, wherein each ring structure comprises segments of equal size.

18. The printed circuit board according to claim 16, wherein the segments of each ring structure are circle segments.

19. The printed circuit board according to claim 16, wherein the circle segments of all the ring structures of one row have the same radial width.

20. The printed circuit board according to claim 16, wherein four segments are provided for each ring structure.

21. The printed circuit board according to claim 16, wherein for each ring structure, the separating regions have the same width.

22. The printed circuit board according to claim 16, wherein the separating regions between the segments of all the ring structures of one row all have the same width.

23. The printed circuit board according to claim 16, wherein some through-contacting bore holes extend from one printed circuit board layer, on which they are provided with contact areas, towards an inner layer provided with test area ring structures.
